(19) United States
(12) Patent Application Publication
(10) Pub. No.: US 2010/0035416 A1
(43) Pub. Date: Feb. 11, 2010

(54) Forming III-Nitride Semiconductor Wafers Using Nano-Structures

(76) Inventors: Ding-Yuan Chen, TAICHUNG (TW); Wen-Chih Chiou, Miaoli (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 12/189,651

(22) Filed: Aug. 11, 2008

(51) Int. Cl. H01L 21/20

(52) U.S. Cl. 438/481; 438/492; 257/E21.133

(57) ABSTRACT

A method of forming a circuit structure includes providing a substrate; etching the substrate to form nano-structures; and growing a compound semiconductor material onto the nano-structures using epitaxial growth. Portions of the compound semiconductor material grown from neighboring ones of the nano-structures join each other to form a continuous compound semiconductor film. The method further includes separating the continuous compound semiconductor film from the substrate.

### TECHNICAL FIELD

This invention relates generally to semiconductor device manufacturing processes, and more particularly to forming group-III nitride films.

### BACKGROUND

Group-III nitride (often referred to as III-nitride, or III-N) compounds, such as gallium nitride (GaN) and its related alloys, have been under intense research in recent years due to their promising applications in electronic and optoelectronic devices. Particular examples of potential optoelectronic devices include blue light emitting diodes and laser diodes, and ultra-violet (UV) photo-detectors. The large bandgap and high electron saturation velocity of the III-nitride compounds also make them excellent candidates for applications in high-temperature and high-speed power electronics.

Due to the high equilibrium pressure of nitrogen at typical growth temperatures, it is extremely difficult to obtain GaN bulk crystals. Owing to the lack of feasible bulk growth methods, GaN is commonly deposited epitaxially on substrates such as SiC and sapphire (Al₂O₃) substrates. However, a current problem with the manufacturing of GaN thin films is that there is no readily available suitable substrate material whose lattice constant and thermal expansion coefficient closely matching that of GaN. Among the possible substrates for GaN, silicon substrates were explored, although the lattices of silicon substrates do not match that of GaN. Silicon substrates are attractive for GaN growth given their low cost, large diameter, high crystal and surface quality, controllable electrical conductivity, and high thermal conductivity. The use of silicon substrates promises easy integration of GaN based optoelectronic devices with silicon-based electronic devices.

Additionally, due to the lack of appropriate substrates for growing GaN films thereon, the sizes of the GaN films are limited. Large GaN films will result in great stresses between the GaN films and the underlying substrates, and hence cause the bowing of the substrates. This may cause several adverse effects. First, a great number of defects (dislocations) will be generated in the supposedly crystalline GaN films. Second, the thicknesses of the resulting GaN films will be less uniform, causing wavelength shift of the light emitted by the optical devices formed on the GaN films. Third, cracks may be generated in large stressed GaN films.

Epitaxial lateral overgrowth (ELOG) technique has been used to form GaN films with reduced stress and reduced dislocations therein. However, conventional ELOG processes are time consuming and costly.

A process was proposed to grow a GaN film on GaN nano-structures, as shown in FIG. 1. Sapphire substrate 10 is first provided and placed in a chamber. Process gases including NH₃, GaCl, N₂, and H₂ are then introduced, and hydride vapor phase epitaxy (HVPE) is used to form nitride layers 11 and GaN nano-columns 12 on nitride layers 11. Process conditions are then changed to induce lateral overgrowth, forming GaN film 15. After the formation of GaN film 15, sapphire substrate 10 and the overlying structure is cooled down, causing the breaking of nano-structures 11 and 12, and hence GaN film 15 and sapphire substrate 10 may be separated, at least partially. A mechanical force may also be applied to fully separate GaN film 15 from sapphire substrate 10.

The above-discussed formation process, however, suffers from drawbacks. Since nano-structures 11 and 12 are formed through optimizing process conditions, the dimensions, the pattern density, and the uniformity of nano-structures 11 and 12 are difficult to control. This may affect the thickness uniformity of the resulting GaN film 15. Furthermore, in the case the nano-structures have undesirably great widths; a great mechanical force may be needed in order to separate GaN film 15 from sapphire substrate 10. This not only causes more dislocations to be generated in GaN film 15, but also causes the breaking of GaN film 15, which is typically thin. New methods are thus needed to solve the above-discussed problems.

### SUMMARY OF THE INVENTION

In accordance with one aspect of the present invention, a method of forming a circuit structure includes providing a substrate; etching the substrate to form nano-structures; and growing a compound semiconductor material onto the nano-structures using epitaxial growth. Portions of the compound semiconductor material grown from neighboring ones of the nano-structures join each other to form a continuous compound semiconductor film. The method further includes separating the continuous compound semiconductor film from the substrate.

In accordance with another aspect of the present invention, a method of forming a circuit structure includes providing a substrate; patterning a top portion of the substrate to form nano-columns having a periodic pattern with a substantially uniform pattern density; epitaxially growing a group-III nitride semiconductor film onto the nano-columns; and separating the group-III nitride semiconductor film from the substrate by breaking the nano-columns.

In accordance with yet another aspect of the present invention, a method of forming a circuit structure includes providing a substrate, which includes a buried oxide layer and a silicon layer on the buried oxide layer; patterning the silicon layer and at least a top layer of the buried oxide layer to form nano-columns; epitaxially growing a group-III nitride semiconductor film onto the nano-columns; and separating the group-III nitride semiconductor film from the substrate by breaking the nano-columns.

In accordance with yet another aspect of the present invention, a circuit structure includes a substrate; nano-columns over the substrate, wherein each of the nano-columns includes a top portion and a bottom portion; and a compound semiconductor film on the nano-columns, wherein the compound semiconductor film and the top portion of each of the nano-columns include different materials.

In accordance with yet another aspect of the present invention, a circuit structure includes a substrate; and nano-columns over the substrate and arranged in a periodic pattern. Each of the nano-columns includes a top portion including silicon. The circuit structure further includes a bottom portion underlying the top portion, wherein the top portion and the bottom portion are formed of different materials; and a group-III nitride semiconductor film on the nano-columns.

Advantageous features of the present invention include improved control in the formation of the group-III nitride semiconductor film, and hence the quality of the group-III nitride semiconductor film is improved.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional process for forming a GaN film on nano-structures, wherein the nano-structures are formed by adjusting formation processes; and

FIGS. 2A through 8 are cross-sectional views of intermediate stages in the manufacturing of the embodiments of the present invention.

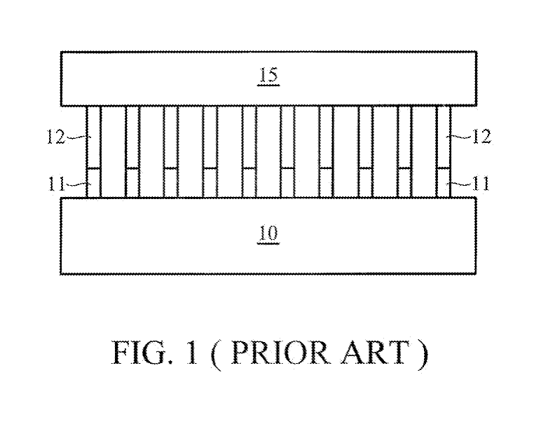

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming group-III nitride (referred to as “III-nitride” hereinafter) semiconductor films and the resulting structures are provided. The intermediate stages of manufacturing a preferred embodiment of the present invention are illustrated. The variations of the preferred embodiments are then discussed. Throughout the various views and illustrative embodiments of the present invention, like reference numbers are used to designate like elements.

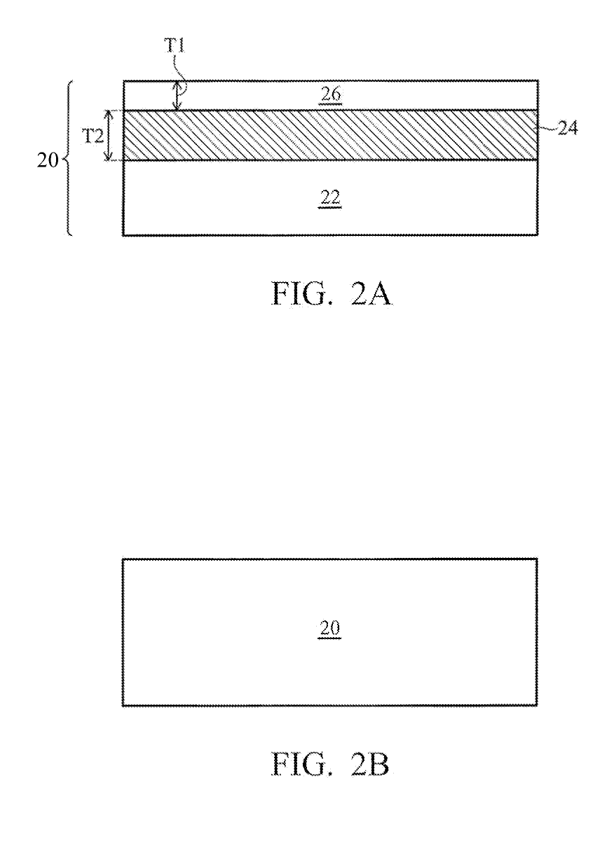

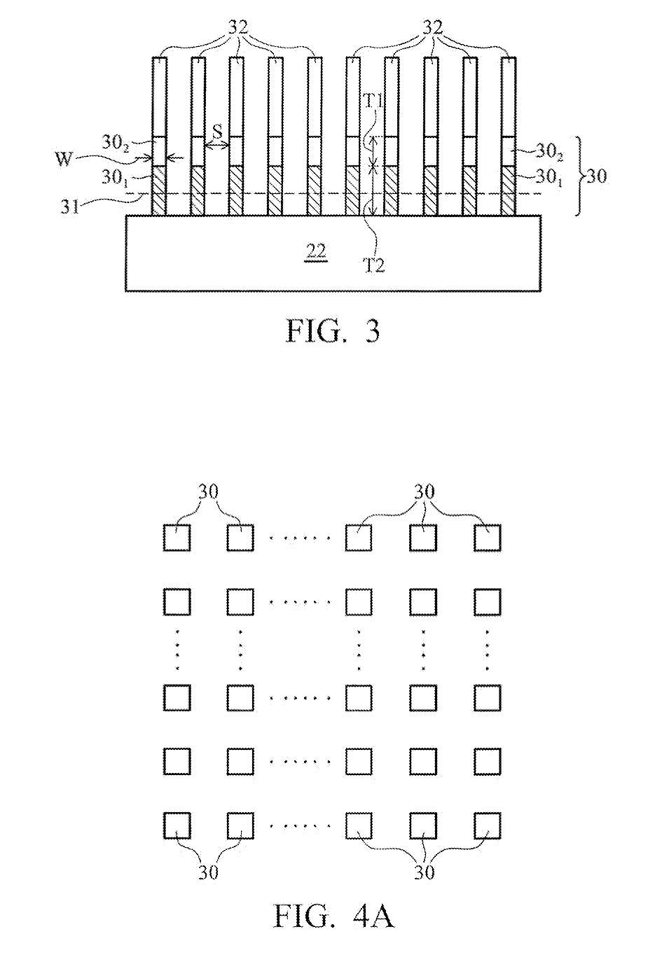

FIGS. 2A and 2B illustrate substrate 20. Referring to FIG. 2A, in an embodiment, substrate 20 has a silicon-on-insulator (SOI) structure including buried oxide layer 24 on silicon layer 22, and silicon layer 26 on buried oxide layer 24. Silicon layer 26 may have a (111) surface orientation, although silicon layer 26 may have other surface orientations such as (100) and (110). Buried oxide layer 24 may include silicon oxide (SiO₂) or other dielectric materials. Alternatively, buried oxide layer 24 is formed of other materials other than oxides, which may include dielectric materials such as SiNₓ, SiON, semiconductor materials such as SixGe₍₁₋ₓ₎, SiₓC₍₁₋ₓ₎, and conductive materials such as Al, TiN, and the like. Preferably, the material of buried oxide layer 24 is so selected that the coefficient of thermal expansion (CTE) of buried oxide layer 24 significantly mismatches the CTE of the overlying silicon layer 26, the CTE of the underlying silicon layer 22, and/or the CTE of the subsequently formed III-nitride film 40 (not shown in FIG. 2A, please refer to FIG. 5). In an exemplary embodiment, the CTE of buried oxide layer 24 is greater than about 110 percent, or less than about 90 percent of at least one, and possibly both of the CTEs of silicon layers 22 and 26. In other words, the mismatch of the CTE of buried oxide layer 24 to the overlying and underlying features is preferably greater than about 10 percent. Further, the material of buried oxide layer 24 is also selected so that substantially no III-nitride material is grown on nano-column portions 30, (the remaining portion of layer 24 after a subsequent patterning, refer to FIG. 3) in the subsequent formation process of III-nitride film 40 (refer to FIG. 5). Throughout the description, although layer 26 is referred to as being a silicon layer, it may also be formed of other materials that are suitable for forming desirable III-nitride films thereon, including, for example, silicon carbon (SiC), aluminum nitride (AlN), indium nitride (InN), zinc oxide (ZnO), or the like. In an exemplary embodiment, the thickness T1 of silicon layer 26 is between about 10 nm and about 10 μm, and the thickness T2 of buried oxide layer 24 is between about 10 nm and about 10 μm. FIG. 2B illustrates a bulk substrate 20, which may be formed of essentially the same materials as that of layer 26 such as silicon or SiC.

Referring to FIG. 3, a patterning is performed to form nano-columns 30 using photo lithography. For example, photo resist 32 is formed and developed, and then portions of silicon layer 26 and at least an upper portion of buried oxide layer 24 are etched. Buried oxide layer 24 may be etched until the underlying silicon layer 22 is exposed. Alternatively, the etch stops before buried oxide layer 24 is etched through, as shown by dashed line 31, which indicates where the etch stops. The remaining portions of silicon layer 26 and buried oxide layer 24 form nano-columns 30, which include lower portions 30, formed of the remaining portions of buried oxide layer 24, and upper portions 302 formed of the remaining portions of silicon layer 26. Preferably, the lateral dimension (width W or a length) of nano-columns 30 is in the range between about 5 nm and about 900 nm. Accordingly, columns 30 are referred to as nano-columns. It is realized, however, that the dimensions recited throughout the description are merely examples, and may be changed if different formation technologies are used, or the materials of nano-columns 30 and III-nitride film 40 (refer to FIG. 5) are changed. The distance S between the neighboring nano-columns 30 may be between about 5 nm and about 900 nm. To ensure that the spacing between nano-columns 30 are not fully filled with III-nitride material in the subsequent formation of III-nitride film 40 (refer to FIG. 5), the aspect ratio of the spacings, which may equal (T1+T2)/S, is preferably greater than 1, and more preferably greater than about 4.

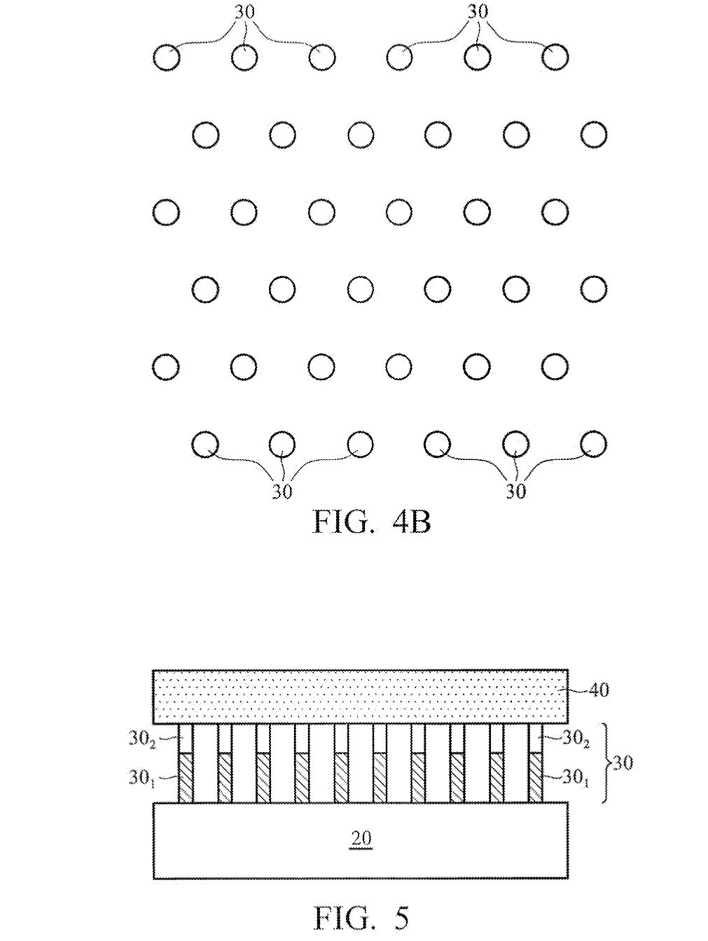

FIGS. 4A and 4B illustrate top views of the structure shown in FIG. 3, wherein two of the possible arrangement schemes of nano-columns 30 are illustrated. In FIG. 4A, nano-columns 30 are arranged as an array. In FIG. 4B, nano-columns 30 are arranged in the shape of beehive cells. It is appreciated that nano-columns 30 may be arranged in any pattern, providing the pattern density uniformity of nano-columns 30 is substantially uniform in local regions and throughout the entire substrate 20 (which may be throughout the entire respective semiconductor chip or the entire wafer). The top view of individual nano-columns 30 may have any shape, for example, squares as shown in FIG. 4A, or circles as shown in FIG. 4B.

Referring to FIG. 5, III-nitride film 40 is epitaxially grown. In the preferred embodiment, III-nitride film 40 is formed of GaN. In other embodiments, III-nitride film 40 may comprise semiconductor materials such as InGaN, AlInGaN, the combinations of GaN, InGaN and/or AlInGaN, or the like. Preferably, the epitaxial growth is selective, and substantially does not occur on the exposed surfaces of nano-column portions 301. On the other hand, the epitaxial growth occurs on the exposed surfaces of nano-column portions 302. The growth has two components, a vertical component for growing the III-nitride film 40 upward, and a lateral component. Advantageously, the lateral growth of the III-nitride film 40 results in less dislocations to be generated, and hence the quality of III-nitride film 40 is improved. The lateral component of the epitaxial growth eventually causes the portions of III-nitride materials grown from neighboring nano-columns 30 to join each other to form a continuous III-nitride film 40. It is realized that although not shown in FIG. 5, the same material as III-nitride film 40 also forms on the sidewall of nano-column portions 302. However, with appropriate T1/S ratio, III-nitride film 40 seals the spacings between nano-columns 30 before the III-nitride material substantially fills the spacing between nano-column portions 302. Advantageously, with the III-nitride material not grown on nano-column portions 301, even if the spacing between nano-column portions 302 are substantially fully filled, nano-column portions 30, are still left uncovered by the III-nitride material, and can be used to separate III-nitride film 40 from substrate 20. Accordingly, in alternative embodiments, the spacings between nano-column portions 302 are substantially fully filled, with substantially no filling into the spacings between nano-column portions 301.

The formation methods of III-nitride film 40 include, but are not limited to, metal organic chemical vapor deposition (MOCVD), physical vapor deposition, molecular beam epitaxy (MBE), hydride vapor phase epitaxy (HVPE), liquid phase epitaxy (LPE), and other applicable deposition methods. The temperature for the growth of III-nitride film 40 is preferably greater than about 500° C., and more preferably between about 700° C. and about 1100° C. In the case III-nitride film 40 comprises GaN, the process gases for forming III-nitride film 40 may include GaCl, NH₃, and carrier gases, although alternative process gases comprising Ga and N may also be used. Through the reaction between GaCl and NH₃, GaN may be deposited.

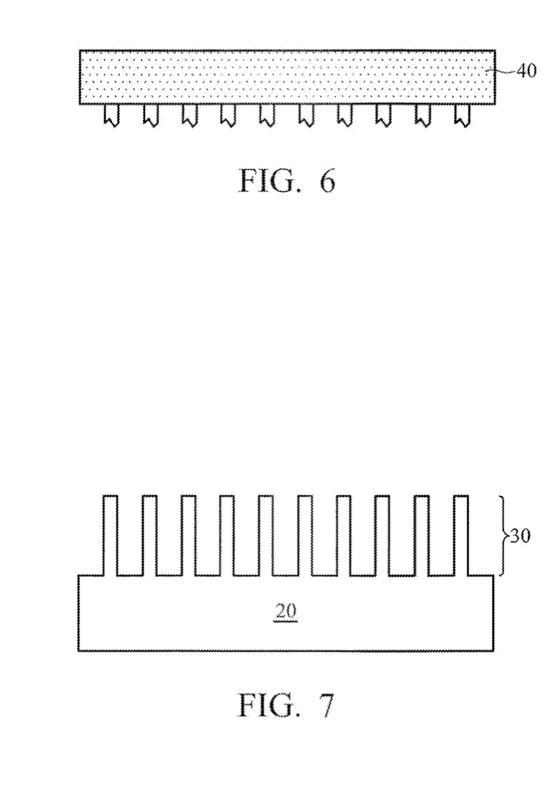

III-nitride film 40 is deposited to a desirable thickness, which may be, for example, greater than about 1000 nm. The resulting structure is then cooled down. It is realized that III-nitride film 40 is grown at a high temperature. When cooled down, the difference in the CTEs of nano-columns 30 (which may have upper portions and bottom portions having different CTEs), substrate 20, and III-nitride film 40 causes stress to be applied on nano-columns 30 during the cooling down process, resulting in nano-columns 30 to be broken. Additional twisting force may also be applied to fully separate III-nitride film 40 from substrate 20. The resulting III-nitride film 40 is shown in FIG. 6. III-nitride film 40 may then be polished and/or sawed. Advantageously, nano-columns 30 include bottom portions that have increased CTE mismatch with the overlying and underlying material, and hence the possibility that nano-columns 30 break during the cooling down process increases. Accordingly, a smaller force, if any, is needed to twist III-nitride film 40 against substrate 20 in order to break nano-columns 30. Alternatively, nano-column portions 301, which may be an oxide, are etched using a HF-based solution.

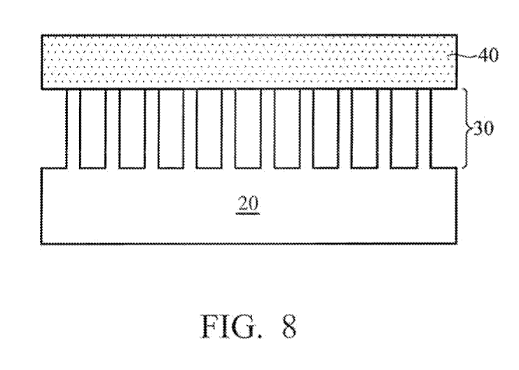

Referring to FIG. 7, in the case the substrate 20 is a bulk substrate (as shown in FIG. 2B), nano-columns 30 are formed by etching substrate 20, using essentially the same methods as forming the nano-columns 30 as shown in FIG. 3. The dimensions of nano-columns and the spacings between nano-columns 30 may also be essentially the same as described in the preceding paragraphs. Next, as shown in FIG. 8, III-nitride film 40 is formed on nano-columns 30, using essentially the same method as described in the preceding paragraphs. Again, since III-nitride film 40 is formed at a high temperature, the difference in the CTEs of substrate 20 and III-nitride film 40 causes the breaking of nano-columns 30 in the cooling down process.

The embodiments of the present invention have several advantageous features. First, since the nano-columns are formed by lithography techniques, the dimension, the pattern density, and the uniformity of the nano-columns can be controlled precisely. This results in improved quality in the resulting III-nitride film formed thereon. Second, since the III-nitride film is formed on the nano-columns, significant lateral growth is resulted, and hence the dislocation in the III-nitride film is reduced. Third, with the materials and the width of nano-columns being controllable, a smaller twisting force is needed to break the nano-columns. Fourth, since III-nitride film 40 is not grown on nano-column portions 301, the nano-column portions 30, is ensured to be mechanically weak portions that can be broken or wet etched easily.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a circuit structure, the method comprising:
providing a substrate;
etching the substrate to form nano-structures; and
growing a compound semiconductor material onto the nano-structures using epitaxial growth, wherein portions of the compound semiconductor material grown from neighboring ones of the nano-structures join each other to form a continuous compound semiconductor film.

2. The method of claim 1 further comprising separating the continuous compound semiconductor film from the substrate.

3. The method of claim 1, wherein the substrate comprises a first layer, a second layer on the first layer, and a third layer on the second layer, wherein the second layer and the third layer comprise different materials.

4. The method of claim 3, wherein after the step of etching, portions of the first layer are exposed, and wherein the nano-structures are nano-columns, with each of the nano-columns comprising a portion of the second layer and a portion of the third layer.

5. The method of claim 3, wherein the third layer is a silicon layer, and the second layer is a buried oxide layer.

6. The method of claim 1, wherein the substrate is a bulk substrate, and wherein after the step of etching the substrate, portions of a top layer of the substrate are removed, and remaining portions of the top layer of the substrate form the nano-structures.

7. The method of claim 1, wherein the compound semiconductor material comprises a group-III nitride semiconductor material.

8. The method of claim 7, wherein the group-III nitride semiconductor material comprises gallium nitride (GaN).

9. A method of forming a circuit structure, the method comprising:
providing a substrate;
patterning a top portion of the substrate to form nano-columns having a periodic pattern with a substantially uniform pattern density;
epitaxially growing a group-III nitride semiconductor film onto the nano-columns; and
separating the group-III nitride semiconductor film from the substrate by breaking the nano-columns.

10. The method of claim 9, wherein the step of patterning the top portion of the substrate comprises etching the substrate using photo lithography.

11. The method of claim 9, wherein the nano-columns having a periodic pattern with a substantially uniform pattern density are formed throughout an entirety of the substrate.

12. The method of claim 9, wherein the nano-columns have a width less than about 900 nm.

13. The method of claim 9, wherein spacings between the nano-columns have an aspect ratio of greater than about 4.

14. The method of claim 9, wherein the substrate is a silicon-on-insulator substrate comprising a silicon layer on a buried oxide layer, and wherein the nano-columns comprise portions of the silicon layer and portions of the buried oxide layer.

15. The method of claim 9, wherein the substrate is a bulk silicon substrate.

16. The method of claim 9, wherein the group-III nitride semiconductor film comprises gallium nitride (GaN).

17. A method of forming a circuit structure, the method comprising:
providing a substrate comprising:
a buried oxide layer; and
a silicon layer on the buried oxide layer;
patterning the silicon layer and at least a top layer of the buried oxide layer to form nano-columns;
epitaxially growing a group-III nitride semiconductor film onto the nano-columns; and
separating the group-III nitride semiconductor film from the substrate by breaking the nano-columns.

18. The method of claim 17, wherein the substrate further comprises a bottom layer underlying the buried oxide layer, and wherein after the step of patterning, portions of the bottom layer are exposed.

19. The method of claim 17, wherein only an upper portion of the buried oxide layer is patterned by the step of patterning.
